(19) United States
(12) Patent Application Publication
(10) Pub. No.: US 2025/0209027 A1
(43) Pub. Date: Jun. 26, 2025

(54) RESILIENT I/O INTERCONNECT

(71) Applicant: Intel Corporation, Santa Clara, CA (US)

(72) Inventors: Gregory K. CHEN, Portland, OR (US); Phil KNAG, Sherwood, OR (US); Carlos TOKUNAGA, Hillsboro, OR (US); Wei WU, Portland, OR (US)

(21) Appl. No.: 18/394,332

(22) Filed: Dec. 22, 2023

(51) Int. Cl. G06F 13/40; H01L 25/065

(52) U.S. Cl. CPC G06F 13/4027; H01L 25/0652

(57) ABSTRACT

Disclosed are interconnect systems with spatially separated redundant interconnects to replace faulty interconnects. In some embodiments, error correction code techniques may also be used to enhance communications robustness.

### TECHNICAL FIELD

Embodiments disclosed herein relate to the field of integrated circuits; and more specifically, to interconnect circuits for coupling integrated circuits to one another.

### BRIEF DESCRIPTION OF THE DRAWINGS

The disclosure may best be understood by referring to the following description and accompanying drawings that are used to illustrate embodiments of the invention. In the drawings:

FIGS. 1A-1C are diagrams showing an exemplary multi-chiplet 3D processing system in accordance with some embodiments.

FIGS. 2A-2E are diagrams illustrating an interconnect architecture in accordance with some embodiments.

FIG. 3 is a circuit block diagram illustrating an interconnect system for communications between connected interconnect section tiles in accordance with some embodiments.

FIG. 4 illustrates an example computing system in accordance with some embodiments.

FIG. 5 is a block diagram of an example processor and/or SoC suitable for use in the system of FIG. 4 in accordance with some embodiments.

### DETAILED DESCRIPTION

Integrated circuit (IC) chiplets in packages such as 3D packages work better with high-speed and reliable interconnect schemes between the different chiplet layers. Disclosed are reliability solutions for multi-chip interconnect systems such as with HBI based interconnect schemes. In some embodiments, approaches may use a first layer of protection utilizing redundant interconnects to replace faulty interconnects with limited amounts of overhead. In some embodiments, a second layer of protection using error correction code techniques may also be employed to reduce additional faults not covered using physical replacement alone.

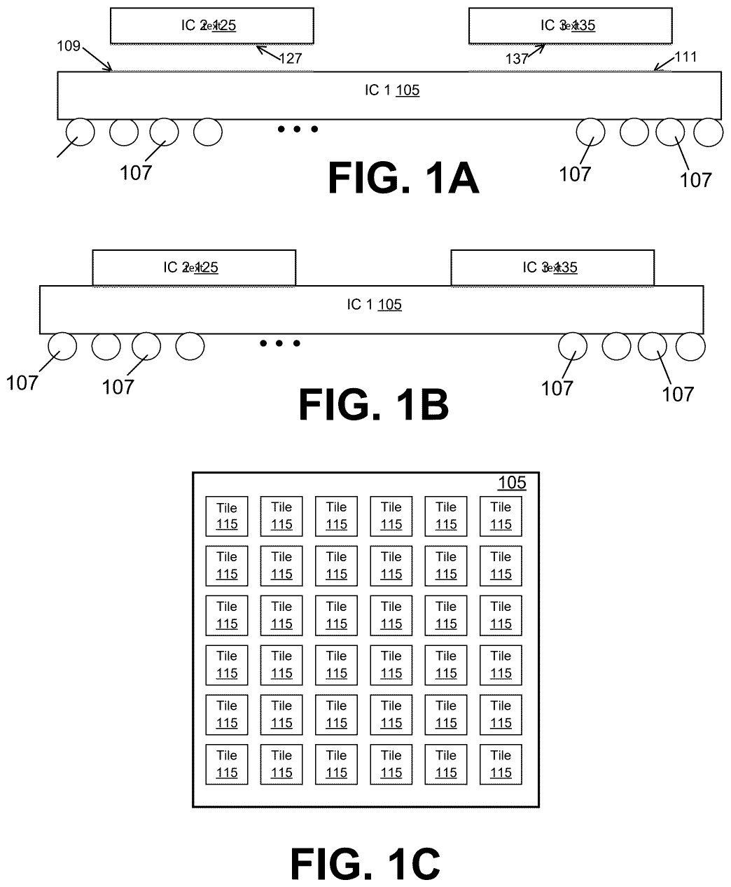

FIGS. 1A-1C are diagrams showing an exemplary multi-chiplet, multi-layer (3D) processing system in accordance with some embodiments. In this example, there are three integrated circuits (dies or chiplets), a first IC 105 and second and third ICs, 135, to be operably mounted atop the first IC 105. The first IC 105 has electrical contacts such as bumps, or micro-bumps, 107 on an underside to connect the first IC 105 to a circuit card, circuit board, motherboard, or the like. It also has contacts 109 and 11 to connect with corresponding contacts 127, 137, respectively, from the second and third ICs 125, 135. For example, complementary contacts to be connected, 109/125 and 111/137, may be implemented with hybrid contacts (HBCs) or with other suitable contact structures to facilitate a multi-lane interconnect system between the connected together ICs. (Note that the first die may or may not have bumps 107, depending for example, on the stage of manufacturing. hybrid contacts may be connected in a wafer-to-wafer or die-to-wafer, or die-to-die scheme where the bumps may not yet have been added to the first IC 105.)

FIG. 1A shows the ICs 125, 135 before being mounted to the first IC, while FIG. 1B shows the three ICs after having been mounted together. The ICs could constitute any suitable combination of desired functional IC devices. For example, the first die 105 could be a compute (a.k.a. CPU), system-on-chip (SoC), system on package (SoP), application processing unit (APU), a memory module, or the like. Similarly, the second and third ICs could be any suitable IC, or IC combination, although they will typically provide complementary functionality to the first IC 105 or to each other. For example, the second and third ICs 125, 135 could be memory modules, accelerators, graphics processing units (GPUs), or other processing systems. In the depicted example, the corresponding contact set pairs 109/127 and 111/137 may provide power supplies from the first IC to the second and third ICs, as well as high speed IO (input/output) interconnectivity between the connected-together ICs. If the contacts are hybrid contacts, the IO inter-connections may be said to be hybrid interconnects (HBIs) or direct bond interconnects (DBIs). In some embodiments, HBIs, or DBIs, may be desirable since they can have very small footprints, e.g., with pitches less than 10 microns. As used herein, the term “interconnect” refers to an IO (input/output) link, or lane, that is formed when a pair of complementary contacts from first and second integrated circuits (ICs) are connected together. An interconnect may include the physical channel formed at least partially from the connected contacts, as well as IO PHY circuitry (e.g., transmitters, receivers) in the first and second ICs at either ends of the channel. An interconnect section refers to a part of an interconnect that is disposed in one of the two ICs that are connected or are to be connected. Thus, first and second ICs may have complementary interconnect sections that when connected together constitute an interconnect. An interconnect tile refers to a plurality of interconnects, and an interconnect section tile (or tile of interconnect sections) refers to a plurality of interconnect sections in an IC.

FIG. 1C is a diagram showing a plurality of interconnect tiles from a top view looking downward. The interconnect tiles 115 each include an array of interconnects. They may be distributed in any suitable manner for facilitating interconnects within the connected-together contacts 109/127 and 111/137.

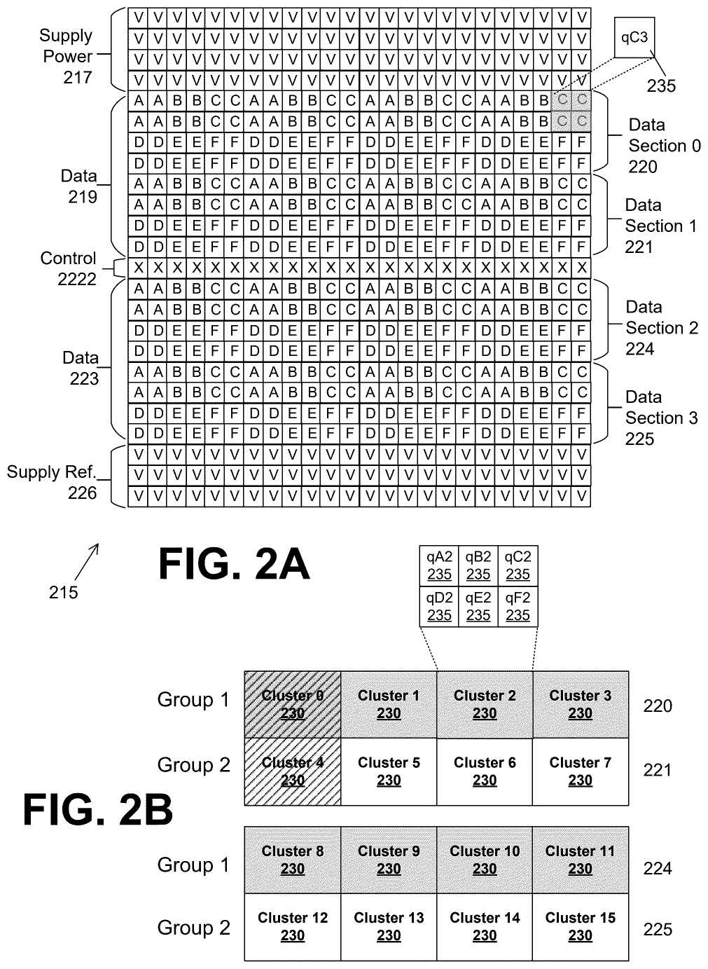

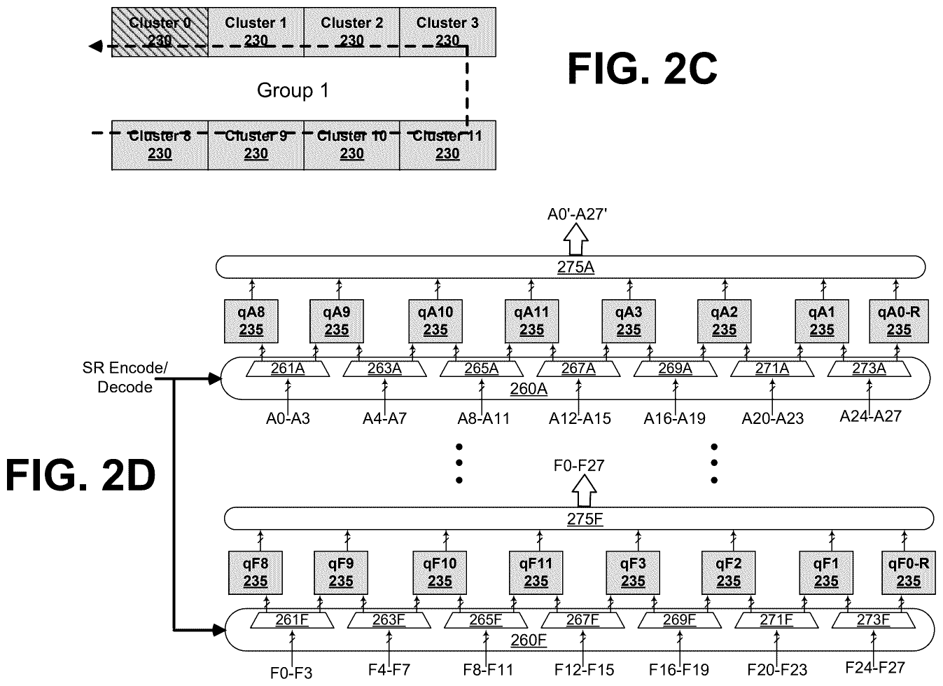

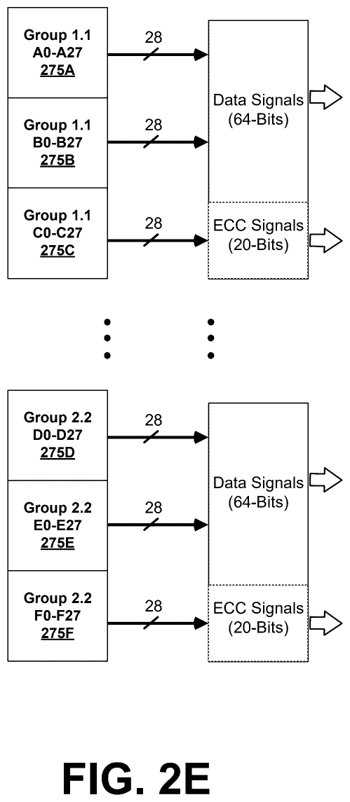

FIGS. 2A-2E are diagrams illustrating a tile interconnect architecture in accordance with some embodiments. In the depicted embodiment, each tile has 24 columns and 24 rows of connected-together contacts, some of which are used for interconnects and others for supply rails.

With the example depicted in FIG. 2A, the rows are organized in the following manner.

The top four rows 217 are used for supply power (e.g., Vcc) rails, while the bottom three rows 226 are used for supply reference (Vss) rails. A middle row 222 is used for control signal interconnects such as for clocks and request/grant signals in a hand-shaking scheme. The remaining rows are divided into an upper portion 219 of eight signal interconnect rows and a lower portion 223 of eight signal interconnect rows. Accordingly, there is a total of 24×16 (=384) signal interconnects per tile for the depicted implementation.

For spatially separated redundancy, as will be further described below, the interconnects are assigned to one of six different classifications, A, B, C, D, E, or F. The interconnects are also organized into 2×2 signal interconnect units 235 with each unit having four interconnects of the same class designation. For example, as shown in FIG. 2A, signal unit qC3 is highlighted. The unit is connoted “qC3” because it is a “quad” unit (4 interconnects); it includes “C” class interconnects; and it is the third C-set unit in the tile. The rows are also organized into four signal row sections 220, 221, 224, and 225, as indicated, with each section having eight clusters 230 each composed of one of each of the six different class units.

FIG. 2B depicts the row sections 220, 221, 224, and 225 at a higher level showing their constituent clusters 230. There are 16 clusters (Cluster 0 through Cluster 15) organized into two separate groups, groups 1 and 2, with their row sections interleaving one another, spatially separating each group's row sections from the other row section. Thus, in this example, the first group has clusters 0-3 and 8-11, while the second group has clusters 4-7 and 12-15. In some embodiments, each group could constitute a separate NoC (network-on-chip) link between the communicating first and second connected IC agents.

For each group, the cluster in the upper-left corner is reserved as a redundant cluster for the other seven clusters (signal clusters) in the group. (Note that FIG. 2B indicates the redundant clusters using diagonal hatching.)

With the depicted embodiment, interconnects are replaceable at a unit-level granularity. That is, the redundant cluster essentially contains six independently replaceable interconnect units, A-F, which each may be used to replace another unit of the same class from the other seven clusters in the group.

FIGS. 2C-2D are diagrams illustrating how a unit may be replaced in accordance with some embodiments. As an example, FIG. 2C illustrates the clusters in Group 1, showing an exemplary pathway for linking (or chaining) them together in order to be able to efficiently replace any one of the seven data units in any of the cluster classes (A-F) in accordance with some embodiments. FIG. 2D is a schematic diagram showing the separate pluralities of class units (A-F) linked together for efficient replacement of any one of the seven data units. Each class chain includes like-class units 235 from clusters 8-11 and 0-3, with the units from cluster 0 providing the redundant units. The units from each class are coupled to an associated demultiplexer circuit 260, which has a set of 28 incoming signal inputs (e.g., data, ECC, or other), as shown, and channels the signal input pathways through selected units, bypassing any previously identified faulty unit, and directing the signal input paths out through multiplexer circuit 275. For example, the A chain, which includes units qA8, qA9, qA10, qA11, qA3, qaA2, qA1, and qA0 (redundant unit), is coupled to demultiplexer circuit 260A to receive signals A0-A27. Should any one of the units be faulty, the signal paths, beginning with the paths aligned with the faulty unit, are redirected, shifted rightward in this implementation, thereby effectively replacing the faulty unit with the redundant unit. For example, if the 4th unit (qA11) is bad, the signal paths A0-A11 are routed to the first three units (qA8-qA10), while signal paths A12-A27 are redirected through the last four units (qA3-qA0), thereby bypassing the faulty qA11 unit. This replacement scheme can fix a single failing region, i.e., a single unit for each class in a group, but if there are multiple fault regions that are spread out, another approach may be employed to complement the spatial redundancy scheme.

FIG. 2E is a diagram illustrating how an ECC (error correction code) scheme may be used in concert with the exemplary spatial redundancy method described above. The 336 signal interconnects (14 signal clusters each with 28 signal interconnects) on each tile are organized into 4 ECC groups; Group 1.1, Group 1.2, Group 2.1, and Group 2.2. each of these four ECC groups includes 64 data signals and 20 ECC signals. Group 1.1 includes the A, B, and C chained together units from Group 1; Group 1.2 includes the D, E, and F chained together units from Group 1; Group 2.1 includes the A, B, and C chained together units from Group 2; and Group 2.2 includes the D, E, and F chained together units from Group 2.

Any suitable ECC methodology may be used. For example, Tables 1 and 2 show ECC techniques that may be used for ECC groups having up to 127 bits of data. Table 1 shows some random bit correction techniques, while Table 2 lists some symbol-based correction methods. With methods from either category, higher detection even with the same or lower correction may be of value because the likelihood of problematic silent data corruption may be lowered.

TABLE 1
Random Bit Error Methods

| ECC | ECC | | |
|---|---|---|---|
| Method | bits | Correctable | Detectable |
| SECDED | 8 b | 1 | 2 |
| SECTED | 14 b | 1 | 3 |
| DEC | 14 b | 2 | 2 |
| SECQED | 15 b | 1 | 4 |
| DECTED | 15 b | 2 | 3 |

TABLE 2
Symbol Based Correction Methods

| Symbol | ECC | | |
|---|---|---|---|
| errors | bits | Correctable | Detectable |
| SSC | 12 b | 1 symbol | 1 symbol |
| SSCDSD | 18 b | 1 symbol | 2 symbols |

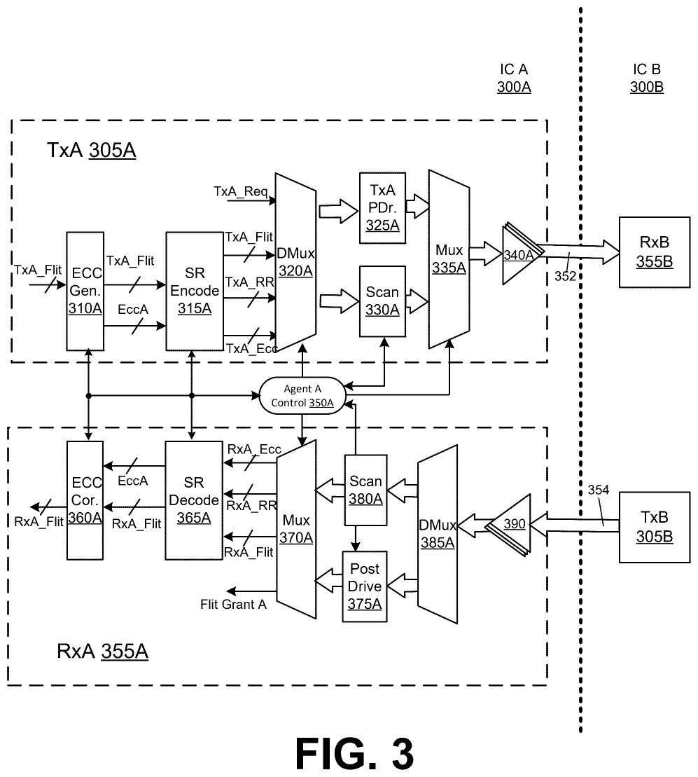

FIG. 3 is a circuit block diagram illustrating an interconnect system for communications between connected interconnect section tiles such as those described above in accordance with some embodiments. For example, one of the interconnect section tiles may be part of a first IC (300A), and the other interconnect section tile may be part of a second IC (300B). The first IC interconnect section tile IO circuitry includes transmitter circuitry 305A, Agent A control circuitry 350A, and receiver A (RxA) circuitry 355A, coupled together as shown. The second IC (IC B) has equivalent circuit blocks including a receiver circuit 355B and a transmitter circuit 305B. The receiver 355B is coupled to transmitter A (305A) through connected-together complementary contact pairs that define a multi-bit physical channel 352 between the first IC transmitter (305A) and the second IC receiver (355B). Likewise, the transmitter 305B is coupled to receiver A (355A) through connected-together complementary contact pairs that define a multi-bit physical channel 354 between the second IC transmitter (305B) and the first IC receiver (355A). Note that for ease of illustration, the first IC Tx/Rx circuitry will be discussed, but it should be understood that the counterpart second IC circuitry may operate in the same or similar manner and therefore need not be described. Moreover, separate unidirectional channels are shown for ease of understanding, but in some embodiments, a single, bi-directional channel could be used, with or without simultaneous bi-directional communications capabilities. Depending on the utilized scheme, for example, if separate multilane channels are used as is depicted, the complementary contact pairs may be divided in order to implement the separate multilane channels, or alternatively, separate interconnect tiles could be used for each multilane channel. As with many aspects of this disclosure, particular implementations will depend on specific design limitations and objectives.

The first IC transmitter (305A) includes ECC generation circuitry 310A, spatial redundancy (SR) encode circuitry 315A, de-multiplexer circuitry (de-mux) 320A, TxA pre-drive circuit block 325A, boundary scan circuitry 330A, multiplexer (mux) circuitry 335A, and TxA driver circuitry 340A, all coupled together as shown.

In operation, a flit of data (TxA_Flit, e.g., 64-bit data flit) to be transmitted to IC B is provided to the ECC generation circuit 310A, which processes the data bits (e.g., 64 data bits such as from an ECC group of FIG. 2E) to generate an ECC code (TxA_Ecc) for the flit. From here, the data flit and ECC code are conveyed to the SR encode circuit 315A, which may implement circuitry similar to the multiplexer system circuitry of FIG. 2D, to configure the particular interconnect paths used for transmitting the flit and ECC signals.

If the system is in a test mode to identify defective interconnect signal pathways, the control circuit 350A will control the de-mux circuit 320A and mux circuit 335A to select the scan block circuit 330A, instead of the TxA pre-drive circuitry 325A, for pathway access to the TxA drivers 340A and channel 352. In some embodiments, using the SR encode circuitry, the scan block, and also feedback from the TxB/RxA link, the control circuit is able to test the various different interconnect paths that make up the TxA/RxB interconnect system, including both the data and redundant unit signal paths. In other embodiments, the tile contact connections themselves may be tested separately, allowing the up and downstream Tx/Rx circuits to be tested without requiring feedback from the other IC. For example, in some embodiments, the TxA circuitry paths up to the channel 352 may also separately be tested using scan chain built-in-self-test (BIST) functionality that may be controlled through a JTAG (Joint Test Action Group) test control interface (not shown).

Once any defective contact paths are identified and bypassed using the redundant interconnects, redundancy configuration codes for selecting the verified pathways are then stored, e.g., for access by control circuit 350A or in the SR circuitry 315A itself, so that the updated paths may be used for normal communications operations.

When in a normal operational mode, the flit data is conveyed through the SR encode circuitry (pathway network), which is encoded to select operational paths as were identified in a test phase. The TxA_RR signal lines correspond to the redundant unit paths, while the TxA_Flit and TxA_Ecc signal lines correspond to the data unit paths (e.g., as described regarding FIGS. 2C-2D). Depending on whether defective units for the TxA_Flit and/or TxA_Ecc lines are identified or not, the TxA_RR lines will be, or will not be, used as needed. That is, coming out of SR encode circuit 315A, the flit and ECC data are conveyed using a combination of hopefully operational lines from the TxA_Flit, TxA_RR, and TxA_ECC lines. IN this way, the SR encode circuitry 315A is able to route the signals to specific physical IO locations within the interconnect system.

When data is to be transmitted under normal operational modes, the de-mux 320A and mux 335A are controlled by control circuit 350A to select the TxA pre-drive circuitry 325A (and not the scan block 330A). The TxA pre-drive circuitry and TxA drive circuitry 340A then drive the data (ECC and flit data) onto the channel 352 and onward to the RxB receiver 355B. In some embodiments, the ECC generation and SR encode circuits may be implemented using combinational logic circuits while the scan and pre-drive circuit blocks may incorporate sequential circuits to clock data received from the SR encode circuitry 315A out of the transmitter. For example, the pre-drive circuitry 325A may include a source-synchronous FIFO (first-in-first-out) buffer for performing clock/data synchronization. (Note that for convenience, clock signals have not been expressly shown but the TxA transmitter has at least some sequential circuits for controlling data flow and data synchronization with the RxB 355B. For example, in some embodiments, a forwarded or source synchronous clocking scheme may be used, with the transmitter 305A forwarding its clock to the receiver 355B. Along these lines, in some embodiments, important clock and handshake signals, e.g., request/grant, may employ hard coded dual-modular redundancy to allow the system to maintain good reliability through redundancy and allow the physical logic design to facilitate quality clock trees with predictable latencies.

The receiver circuit block 355A includes similar blocks as the transmitter (TxA 305A) except they are configured to operate in the opposite direction. The receiver (RxA 355A) includes ECC correction circuitry 360A, SR Decode circuitry 365A, mux circuitry 370A, boundary scan circuitry 380A, receiver A post-driver circuitry 375A, de-mux circuitry 385A, and receiver driver circuits 390A, all coupled together as shown. As with the TxA circuitry, when in a test mode, the control circuitry 350A selects the mux and de-mux circuits (375A, 385A) to enable the boundary scan circuitry 380A for test and identification of defective receiver interconnect paths and other path elements. In some embodiments, this may be performed in cooperation with testing of the transmitter paths, and an overall updated path configuration may be identified and stored, in the control circuitry 350A and/or in the SR encode and decode circuits (315A, 365A) themselves.

When in a normal operational mode, the control circuitry 350A controls the mux/de-mux circuits (370A, 385A) to selectably enable the post driver receiver circuitry 375A to receive, in cooperation with the RxA driver circuitry 390A, to receive data flit and ECC signals from the TxB transmitter through multilane channel 354. The signals are then conveyed through the SR decoder 365A to the ECC correction circuitry where the data flit is then checked and corrected, if errant, and passed out of the receiver for use by the IC.

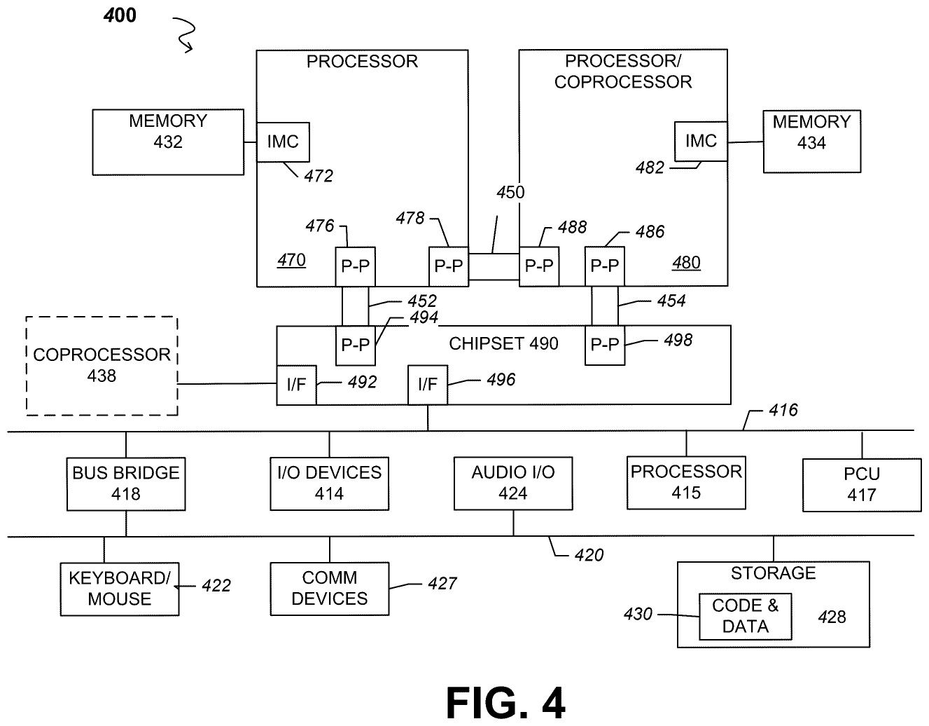

FIG. 4 illustrates an example computing system in accordance with some embodiments. Multiprocessor system 400 is an interfaced system and includes a plurality of processors including a first processor 470 and a second processor 480 coupled via an interface 450 such as a point-to-point (P-P) interconnect, a fabric, and/or bus that may be implemented using spatially redundant interconnect systems as described herein. In some examples, the first processor 470 and the second processor 480 are homogeneous. In some examples, first processor 470 and the second processor 480 are heterogenous. Though the example system 400 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 470 and 480 are shown including integrated memory controller (IMC) circuitry 472 and 482, respectively. Processor 470 also includes interface circuits 476 and 478, along with core sets. Similarly, second processor 480 includes interface circuits 486 and 488, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 470, 480 may exchange information via the interface 450 using interface circuits 478, 488. IMCs 472 and 482 couple the processors 470, 480 to respective memories, namely a memory 432 and a memory 434, which may be portions of main memory locally attached to the respective processors.

Processors 470, 480 may each exchange information with a network interface (NW I/F) 490 via individual interfaces 452, 454 using interface circuits 476, 494, 486, 498. The network interface 490 (e.g., one or more of an interconnect, bus, and/or fabric, and in some examples is a chipset) may optionally exchange information with a coprocessor 438 via an interface circuit 492. In some examples, the coprocessor 438 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 470, 480 or outside of both processors, yet connected with the processors via an interface such as P-P interconnect, such that either or both processors' local cache information may be stored in the shared cache if a processor is placed into a low power mode.

Network interface 490 may be coupled to a first interface 416 via interface circuit 496. In some examples, first interface 416 may be an interface such as a Peripheral Component Interconnect (PCI) interconnect, a PCI Express interconnect, or another I/O interconnect. In some examples, first interface 416 is coupled to a power control unit (PCU) 417, which may include circuitry, software, and/or firmware to perform power management operations with regard to the processors 470, 480 and/or co-processor 438. PCU 417 provides control information to one or more voltage regulators (not shown) to cause the voltage regulator(s) to generate the appropriate regulated voltage(s). PCU 417 also provides control information to control the operating voltage generated. In various examples, PCU 417 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 417 is illustrated as being present as logic separate from the processor 470 and/or processor 480. In other cases, PCU 417 may execute on a given one or more of cores (not shown) of processor 470 or 480. In some cases, PCU 417 may be implemented as a microcontroller (dedicated or general-purpose) or other control logic configured to execute its own dedicated power management code, sometimes referred to as P-code. In yet other examples, power management operations to be performed by PCU 417 may be implemented externally to a processor, such as by way of a separate power management integrated circuit (PMIC) or another component external to the processor. In yet other examples, power management operations to be performed by PCU 417 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 414 may be coupled to first interface 416, along with a bus bridge 418 which couples first interface 416 to a second interface 420. In some examples, one or more additional processor(s) 415, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 416. In some examples, second interface 420 may be a low pin count (LPC) interface. Various devices may be coupled to second interface 420 including, for example, a keyboard and/or mouse 422, communication devices 427 and storage circuitry 428. Storage circuitry 428 may be one or more non-transitory machine-readable storage media as described below, such as a disk drive or other mass storage device which may include instructions/code and data 430 and may implement the storage in some examples. Further, an audio I/O 424 may be coupled to second interface 420. Note that other architectures than the point-to-point architecture described above are possible. For example, instead of the point-to-point architecture, a system such as multiprocessor system 400 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

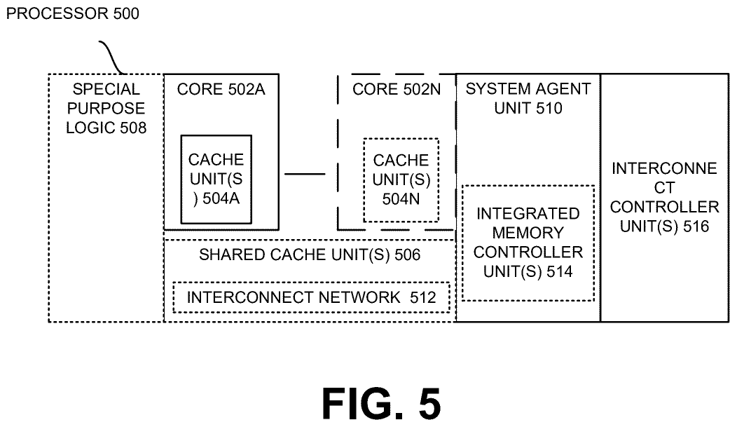

FIG. 5 illustrates a block diagram of an example processor and/or SoC 500 that may have one or more cores and an integrated memory controller. The solid lined boxes illustrate a processor 500 with a single core 502(A), system agent unit circuitry 510, and a set of one or more interface controller unit(s) circuitry 516, while the optional addition of the dashed lined boxes illustrates an alternative processor 500 with multiple cores 502(A)-(N), a set of one or more integrated memory controller unit(s) circuitry 514 in the system agent unit circuitry 510, and special purpose logic 508, as well as a set of one or more interface controller units circuitry 516. Note that the processor 500 may be one of the processors 470 or 480, or co-processor 438 or 415 of FIG. 4.

Thus, different implementations of the processor 500 may include: 1) a CPU with the special purpose logic 508 being integrated graphics and/or scientific (throughput) logic (which may include one or more cores, not shown), and the cores 502(A)-(N) being one or more general purpose cores (e.g., general purpose in-order cores, general purpose out-of-order cores, or a combination of the two); 2) a coprocessor with the cores 502(A)-(N) being a large number of special purpose cores intended primarily for graphics and/or scientific (throughput); and 3) a coprocessor with the cores 502(A)-(N) being a large number of general purpose in-order cores. Thus, the processor 500 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 500 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 504(A)-(N) within the cores 502(A)-(N), a set of one or more shared cache unit(s) circuitry 506, and external memory (not shown) coupled to the set of integrated memory controller unit(s) circuitry 514. The set of one or more shared cache unit(s) circuitry 506 may include one or more mid-level caches, such as level 2 (L2), level 3 (L3), level 4 (L4), or other levels of cache, such as a last level cache (LLC), and/or combinations thereof. While in some examples interface network circuitry 512 (e.g., a ring interconnect) interfaces the special purpose logic 508 (e.g., integrated graphics logic), the set of shared cache unit(s) circuitry 506, and the system agent unit circuitry 510, alternative examples use any number of well-known techniques for interfacing such units. In some examples, coherency is maintained between one or more of the shared cache unit(s) circuitry 506 and cores 502(A)-(N). In some examples, interface controller units circuitry 516 couple the cores 502 to one or more other devices 518 such as one or more I/O devices, storage, one or more communication devices (e.g., wireless networking, wired networking, etc.), etc.

In some examples, one or more of the cores 502(A)-(N) are capable of multi-threading. The system agent unit circuitry 510 includes those components coordinating and operating cores 502(A)-(N). The system agent unit circuitry 510 may include, for example, power control unit (PCU) circuitry and/or display unit circuitry (not shown). The PCU may be or may include logic and components needed for regulating the power state of the cores 502(A)-(N) and/or the special purpose logic 508 (e.g., integrated graphics logic). The display unit circuitry is for driving one or more externally connected displays.

The cores 502(A)-(N) may be homogenous in terms of instruction set architecture (ISA). Alternatively, the cores 502(A)-(N) may be heterogeneous in terms of ISA; that is, a subset of the cores 502(A)-(N) may be capable of executing an ISA, while other cores may be capable of executing only a subset of that ISA or another ISA.
Illustrative examples of the technologies disclosed herein are provided below. An embodiment of the technologies may include any one or more, and any compatible combination of, the examples described below.

Example 1 is an apparatus that includes a first plurality of interconnect sections and a control circuitry. The first plurality of interconnect sections are part of a first integrated circuit (IC). The first plurality of interconnect sections are switchably coupled together through demultiplexer circuitry that has a first set of signal inputs, wherein the first plurality of interconnect sections include one or more redundant interconnect sections. The control circuitry controls the demultiplexer circuitry to redirect one or more of the signal inputs away from one or more faulty interconnect sections from the first plurality of interconnect sections to at least one of the one or more redundant interconnect sections. The first plurality of interconnect sections are to be coupled to complementary interconnect sections from a second IC.

Example 2 includes the subject matter of example 1, and wherein the first IC includes contacts to couple the first IC interconnect sections with the second IC interconnect sections.

Example 3 includes the subject matter of any of examples 1-2, and wherein the contacts are hybrid bonding contacts and the first and second IC interconnect sections are to be coupled together through the hybrid bonding contacts.

Example 4 includes the subject matter of any of examples 1-3, and wherein the first IC includes a second plurality of interconnect sections physically disposed between at least some of the first plurality of interconnect sections.

Example 5 includes the subject matter of any of examples 1-4, and wherein the second plurality of interconnect sections are switchably coupled together through a second demultiplexer circuitry having a second set of signal inputs, wherein the second plurality of interconnect sections includes one or more redundant interconnect sections.

Example 6 includes the subject matter of any of examples 1-5, and wherein the control circuitry is to control the second demultiplexer circuitry to redirect one or more of the second set of signal inputs from one or more faulty interconnect sections to at least one of the one or more redundant interconnect sections within the second plurality of interconnect sections.

Example 7 includes the subject matter of any of examples 1-6, and wherein the second plurality of interconnect sections are to be coupled together with corresponding interconnect sections from the second IC.

Example 8 includes the subject matter of any of examples 1-7, and wherein the plurality of interconnect sections are grouped into units of contiguous interconnect sections, wherein other interconnect sections not part of the plurality of interconnect sections are disposed between any two units of the plurality of interconnect sections.

Example 9 includes the subject matter of any of examples 1-8, and wherein the signal inputs comprise signal lines coupled to error correction code (ECC) circuitry.

Example 10 includes the subject matter of any of examples 1-9, and wherein the first and second ICs are to be part of a 3D IC package.

Example 11 is an apparatus that includes first and second integrated circuits and a plurality of interconnects. The second IC is mounted to the first IC. The first plurality of interconnect units communicatively couple the first IC with the second IC. The first plurality of interconnect units are switchably chained together and include a multiplicity of signal line interconnect units and one or more redundant interconnect units. Any one of the signal line interconnect units may be bypassed and replaced using at least one of the redundant interconnect units.

Example 12 includes the subject matter of example 11, and wherein the interconnects each include a complementary pair of connected-together contacts.

Example 13 includes the subject matter of any of examples 11-12, and wherein the contacts are hybrid bonding contacts and each of the interconnects comprise first and second interconnect sections that are to be connected together through the hybrid bonding contacts.

Example 14 includes the subject matter of any of examples 11-13, and wherein the first and second ICs include a second plurality of interconnect units physically disposed between at least some of the first plurality of interconnect units.

Example 15 includes the subject matter of any of examples 11-14, and wherein the second plurality of interconnect units are switchably chained together and include a second multiplicity of signal line interconnect units and one or more redundant interconnect units.

Example 16 includes the subject matter of any of examples 11-15, and wherein the first and second pluralities of switchably chained interconnect units are coupled together as part of a common error correction code (ECC) section.

Example 17 includes the subject matter of any of examples 11-16, and wherein the first and second ICs include a control circuitry to disengage at least one faulty signal line interconnect unit if present in the second multiplicity of signal line interconnect units and to engage at least one of the redundant interconnect units from the second plurality of interconnect units if the faulty signal line interconnect unit is present in the second plurality of interconnect units.

Example 18 includes the subject matter of any of examples 11-17, and wherein the first plurality of interconnect units include at least four contiguous interconnects.

Example 19 is a processing system that includes first and second ICs and a plurality of interconnect units. The first IC has a plurality of first IC contacts. The second IC has a plurality of second IC contacts connected to the first IC contacts to form complementary contact pairs.

The plurality of interconnect units communicatively couple the first and second ICs together. A first portion of the complementary contact pairs are used as channels for the interconnect units, and a second portion of the complementary contact pairs are used to supply power from the first IC to the second IC. The plurality of interconnect units include a multiplicity of interconnect unit chains each including signal line and redundant interconnect units, wherein for each chain, a detected faulty one of the signal line interconnect units may be replaced in the chain with at least one of the redundant interconnect units.

Example 20 includes the subject matter of example 19, and wherein the contacts are hybrid bonding contacts.

Example 21 includes the subject matter of any of examples 19-21, and wherein the interconnect units in each chain are spaced apart from each other, wherein any two interconnect units in a chain have at least one unit from another chain disposed between them.

Example 22 includes the subject matter of any of examples 19-21, and wherein the interconnect units are each composed of two or more contiguous interconnects.

Example 23 includes the subject matter of any of examples 19-22, and wherein the interconnect units are each composed of a single interconnect.

Example 24 includes the subject matter of any of examples 19-23, and wherein the interconnects are bi-directional interconnects over each complementary contact pair channel.

Example 25 includes the subject matter of any of examples 19-24, and wherein the multiplicity of interconnect unit chains are divided into error correction code (ECC) groups of two or more different chains.

Example 26 includes the subject matter of any of examples 19-25, and wherein the first IC is a compute die and the second IC is a memory die.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors, or other transistor device types such as carbon nanotubes or spintronic devices.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, a system on a chip (SoC), an application processor, an integrated circuit incorporating a combination of one or more of the aforesaid items, etc.

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a first integrated circuit (IC);
a second IC mounted to the first IC; and
a first plurality of interconnect units within the first and second ICs to communicatively couple the first IC with the second IC, wherein the first plurality of interconnect units are switchably chained together and include a multiplicity of signal line interconnect units and one or more redundant interconnect units, wherein any one of the signal line interconnect units may be bypassed and replaced using at least one of the redundant interconnect units.

2. The apparatus of claim 1, wherein the interconnects each include a complementary pair of connected-together contacts.

3. The apparatus of claim 2, wherein the contacts are hybrid bonding contacts and the interconnects comprise first and second interconnect sections that are to be connected together through the hybrid bonding contacts.

4. The apparatus of claim 1, wherein the first and second ICs include a second plurality of interconnect units physically disposed between at least some of the first plurality of interconnect units.

5. The apparatus of claim 4, wherein the second plurality of interconnect units are switchably chained together and include a second multiplicity of signal line interconnect units and one or more redundant interconnect units.

6. The apparatus of claim 5, wherein the first and second pluralities of switchably chained interconnect units are coupled together as part of a common error correction code (ECC) section.

7. The apparatus of claim 5, wherein the first and second ICs include a control circuitry to disengage at least one faulty signal line interconnect unit if present in the second multiplicity of signal line interconnect units and to engage at least one of the redundant interconnect units from the second plurality of interconnect units if the faulty signal line interconnect unit is present in the second plurality of interconnect units.

8. An apparatus, comprising:
a first plurality of interconnect sections that are part of a first integrated circuit (IC), the first plurality of interconnect sections being switchably coupled together through demultiplexer circuitry having a first set of signal inputs, wherein the first plurality of interconnect sections include one or more redundant interconnect sections; and
control circuitry to control the demultiplexer circuitry to redirect one or more of the signal inputs away from one or more faulty interconnect sections from the first plurality of interconnect sections to at least one of the one or more redundant interconnect sections, wherein the first plurality of interconnect sections are to be coupled to complementary interconnect sections from a second IC.

9. The apparatus of claim 8, wherein the first IC includes contacts to couple the first IC interconnect sections with the second IC interconnect sections.

10. The apparatus of claim 9, wherein the contacts are hybrid bonding contacts and the first and second IC interconnect sections are to be coupled together through the hybrid bonding contacts.

11. The apparatus of claim 8, wherein the first IC includes a second plurality of interconnect sections physically disposed between at least some of the first plurality of interconnect sections.

12. The apparatus of claim 11, wherein the second plurality of interconnect sections are switchably coupled together through a second demultiplexer circuitry having a second set of signal inputs, wherein the second plurality of interconnect sections includes one or more redundant interconnect sections.

13. The apparatus of claim 12, wherein the control circuitry is to control the second demultiplexer circuitry to redirect one or more of the second set of signal inputs from one or more faulty interconnect sections to at least one of the one or more redundant interconnect sections within the second plurality of interconnect sections.

14. The apparatus of claim 13, wherein the second plurality of interconnect sections are to be coupled together with corresponding interconnect sections from the second IC.

15. The apparatus of claim 8, wherein the plurality of interconnect sections are grouped into units of contiguous interconnect sections, wherein other interconnect sections not part of the plurality of interconnect sections are disposed between any two units of the plurality of interconnect sections.

16. The apparatus of claim 8, wherein the signal inputs comprise signal lines coupled to error correction code (ECC) circuitry.

17. A processing system, comprising:
a first integrated circuit (IC) having a plurality of first IC contacts;
a second IC having a plurality of second IC contacts connected to the first IC contacts to form complementary contact pairs; and
a plurality of interconnect units to communicatively couple the first and second ICs together, wherein a first portion of the complementary contact pairs are used as channels for the interconnect units, and a second portion of the complementary contact pairs are used to supply power from the first IC to the second IC, wherein the plurality of interconnect units include a multiplicity of interconnect unit chains each including signal line and redundant interconnect units, wherein for each chain, a detected faulty one of the signal line interconnect units may be replaced in the chain with at least one of the redundant interconnect units.

18. The system of claim 17, wherein the interconnect units in the chains are spaced apart from each other, wherein any two interconnect units in a chain have at least one unit from another chain disposed between them.

19. The system of claim 17, wherein the multiplicity of interconnect unit chains are divided into error correction code (ECC) groups of two or more different chains.

20. The system of claim 17, wherein the interconnects are bi-directional interconnects over each complementary contact pair channel.
